(19) United States
(12) Patent Application Publication
(10) Pub. No.: US 2010/0195274 A1
(43) Pub. Date: Aug. 5, 2010

(54) FLOPID STRUCTURE

(76) Inventor: Jonathan Arnold Bell, Culver City, CA (US)

Correspondence Address: Ocean Law, 3463 RED BLUFF CT., Simi Valley, CA, 93063, US

(21) Appl. No.: 12/699,151

(22) Filed: Feb. 3, 2010

Related U.S. Application Data
(60) Provisional application No. 61/149,416, filed on Feb. 3, 2009.

(51) Int. Cl. H05K 7/00; B32B 3/00; F16H 57/00

(52) U.S. Cl. 361/679.01; 428/107; 74/412 R

(57) ABSTRACT

A flopid structure includes flopid elements and engagement members for switching between flexible and rigid states.

### PRIORITY CLAIM

This application claims the benefit of U.S. Provisional Patent Application No. 61/149,416 filed Feb. 3, 2009 for FLOPPY RIGID MECHANISM (FLOPID), and incorporates by reference the entirety of that application for all purposes.

### BACKGROUND OF THE INVENTION

1. Field of the Invention

The present invention relates to flopid structures. In particular, interengagable elements of flopid structures enable selection of alternate floppy and rigid states of a collection of the elements.

2. Discussion of the Related Art

A soft fabric, such as the cloth shown in FIG. 1 provides an example of a floppy structure 100. The draped cloth 102 is characterized by a floppy three dimensional surface 104. Treatments such as starching and pressing can transform the freely draping cloth into a rigid structure 106 with a substantially two dimensional surface 108.

Similarly, a rope can be rigid or floppy. A wet rope becomes rigid when cooled below water's freezing point, but is limp or floppy when sufficiently heated. Tensioning an otherwise floppy rope can also make it rigid. In the cases of starch and freezing water, a dissimilar material undergoing a state change rigidizes the structure. In the tensioning case, continuous application of an external force rigidizes the structure.

Another kind of structure demonstrating rigid and floppy states is a pressurized structure. A good example of this is the tire of a road bike. When properly inflated, the tire is substantially rigid; but, when the pressure is sufficiently reduced, the tire may lose its rigidity together with its desired shape.

With the exception of tensioning examples like the rope, switching a structure from a floppy state to a rigid state and back again requires an application of external force(s) and a considerable period of time. And, even if tensioning is a quick operation, the required use and maintenance of tensioning means can be inconvenient or intolerable in particular applications.

Structures that are switchable between floppy and rigid states and that mitigate energy requirements, external connections such as tensioning means, switching time, or size can beneficially replace existing rigidizing structures and fill needs unmet by traditional rigidizing solutions.

### SUMMARY OF THE INVENTION

The present invention includes flopid structures with interengageable flopid elements. In an embodiment, a flopid structure is for enhancing the utility of a flexible device comprising: a flexible device coupled to an array of flopid elements, the array of flopid elements including plural flopid elements interconnected by one or more flexible members establishing one or more fold lines; where each engagement member of a plurality of rigid engagement members is operable to resist forces tending to flex a flexible member when the engagement member is in a first state and each engagement member operable to present substantially no resistance to forces tending to flex a flexible member when the engagement member is in a second state; and, the flopid array is operable to impart rigidity to the flexible device when the engagement members are in the first state and the flopid array is operable to impart flexibility to the flexible device when the engagement members are in the second state.

In an embodiment, a flopid structure is for enhancing the utility of a flexible device comprising: a flexible device coupled to an array of flopid elements, the array of flopid elements including plural flopid elements and a plurality of engagement members; where each engagement member includes a plurality of engagement segments and each engagement segment is coupled to another engagement segment by a flexible member; each engagement member is engaged with a plurality of the plural flopid elements; each engagement member is operable to resist forces tending to flex the engaged plurality of flopid elements in a first state and each engagement member is operable to present substantially no resistance to forces tending to flex the engaged plurality of flopid elements in a second state; and, the flopid array is operable to impart rigidity to the flexible device when the engagement members are in the first state and operable to impart flexibility to the flexible device when the engagement members are in the second state.

In an embodiment a flopid structure is for enhancing the utility of a flexible device comprising: a flexible device coupled to an array of flopid elements, the array of flopid elements including plural flopid elements; each of the plural flopid elements includes a gear located in a lower gear plane and an engagement member located in an upper engagement member plane; each of the gears interengages at least one other gear; one gear is operable to cause rotation of a plurality of gears and interengagement of a plurality of engagement members for resisting forces tending to flex at least a portion of the array along a fold line in a first state and the gear is operable to cause rotation of a plurality of gears and disengagement of a plurality of engagement members for presenting substantially no resistance to forces tending to flex at least a portion of the flopid array along the fold line in a second state; and, the flopid array is operable to impart rigidity to the flexible device when the engagement members are in the first state and operable to impart flexibility to the flexible device when the engagement members are in the second state.

### BRIEF DESCRIPTION OF THE DRAWINGS

The present invention is described with reference to the accompanying figures. These figures, incorporated herein and forming part of the specification, illustrate embodiments of the invention and, together with the description, further serve to explain its principles enabling a person skilled in the relevant art to make and use the invention.

FIG. 1 shows an example of a floppy structure.

FIGS. 2A-C show first flopid structures in accordance with the present invention.

FIGS. 3A-C show second flopid structures in accordance with the present invention.

FIGS. 4A-B show flopid structures similar to those of FIGS. 2A-C.

FIGS. 4C-E show flopid structures similar to those of FIGS. 3A-C.

FIG. 4F shows a flopid structure having retractable engagement members.

FIG. 4G shows a flopid structure having rotatable engagement arms.

FIGS. 5A-C show flopid structures having a hub with radial engagement members.

FIGS. 6A-C show flopid structures having gears.

FIG. 7 shows an application of flopid structures with sheet form bodies.

FIG. 8 shows an application of flopid structures with scroll form bodies.

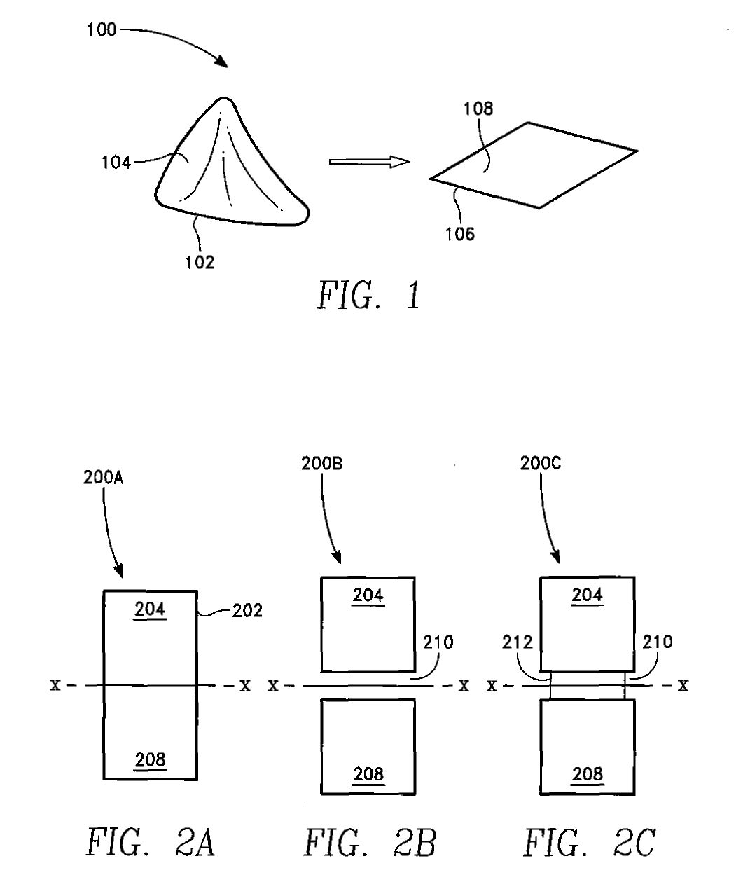

### DETAILED DESCRIPTION OF THE PREFERRED EMBODIMENTS

The disclosure provided in the following pages describes examples of some embodiments of the invention. The designs, figures, and description are non-limiting examples of embodiments of the invention. For example, other embodiments of the disclosed systems and methods may or may not include the features described herein. Moreover, disclosed advantages and benefits may apply to only certain embodiments of the invention and should be not used to limit the disclosed inventions.

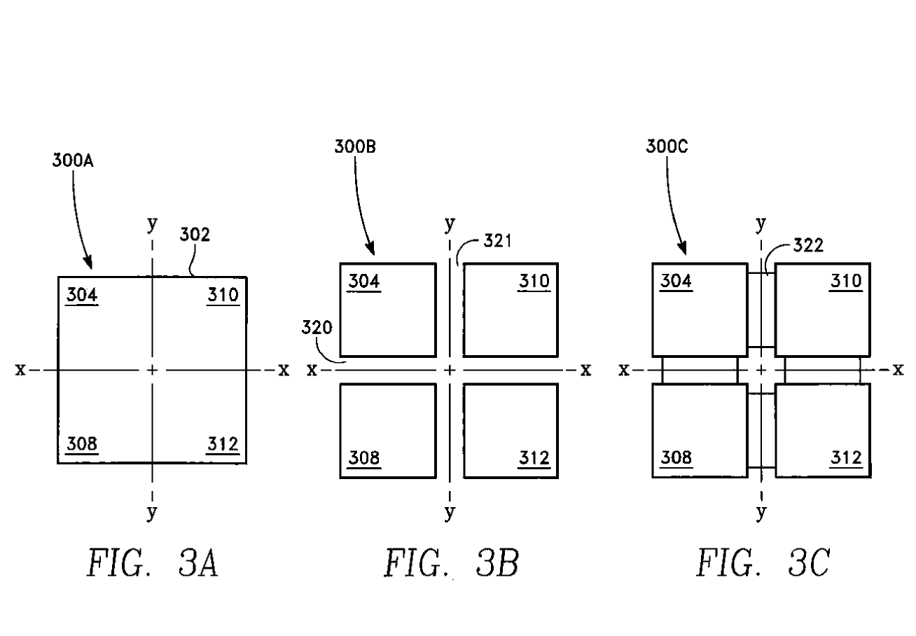

FIG. 2A shows a flopid structure having x-x fold line(s) in accordance with the present invention 200A. Flopid elements 204, 208 comprise a flopid structure 202. A fold line x-x identifies a boundary between the elements. As used herein, fold line includes planar lines, and planar and three dimensional paths that need not be linear. And, as indicated by the context, relative motion between adjacent flopid elements at the fold line includes one or more of rotation and displacement.

FIG. 2B shows spaced apart flopid elements 200B. Flopid element 204 is separated from flopid element 208 by a gap 210 near a fold line x-x.

FIG. 2C shows interconnected flopid elements 200C. In an embodiment, a web 212 is between adjacent flopid elements. In various embodiments, the web is flexible. And, in various embodiments the web is in the form of a membrane or sheet, such as a web of plastic, elastomeric, or resilient material known to persons of ordinary skill in the art. As used herein, flexible indicates a thing or material is intended to bend or flex during at least some anticipated operating conditions. In various embodiments, one or more of the features of FIGS. 2A-C are used in flopid structures mentioned above and below.

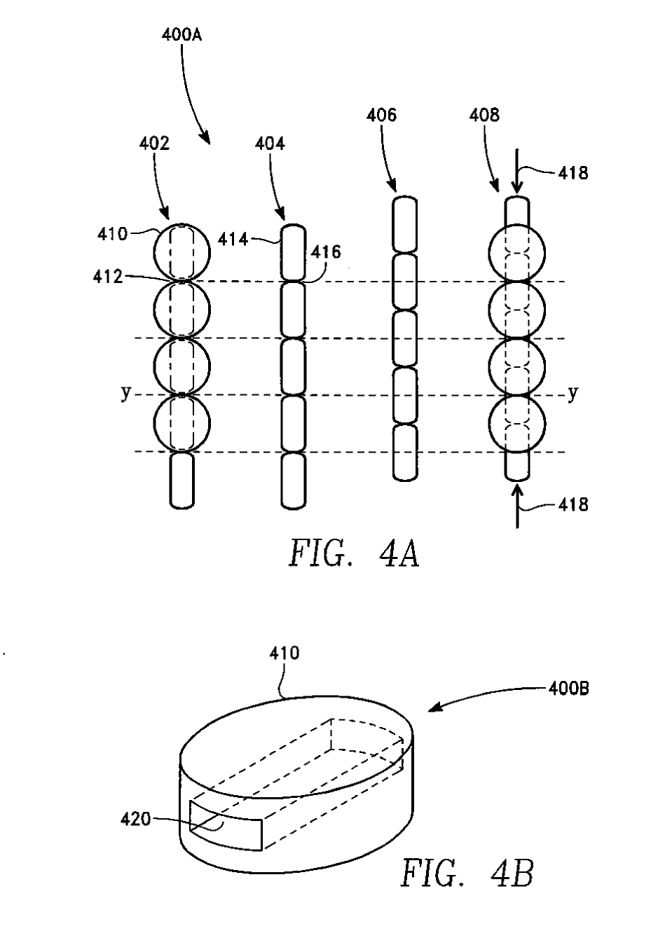

FIG. 3A shows a flopid structure having x-x and y-y fold lines 300A. Flopid elements 304, 308, 310, 312 comprise a flopid structure 302. Fold lines x-x, y-y identify boundaries between the elements.

FIG. 3B shows spaced apart flopid elements 300B. Flopid element 304 is separated from flopid elements 308, 310 by gaps 320, 321 and flopid element 312 is separated from flopid elements 308, 310 by gaps 321, 320.

FIG. 3C shows interconnected flopid elements 300C. In an embodiment, a web 322 is between adjacent flopid elements 304-310, 304-308, 312-308, 312-310. In various embodiments, the web is flexible. And, in various embodiments, one or more of the features of FIGS. 3A-C are used in flopid structures mentioned above and below.

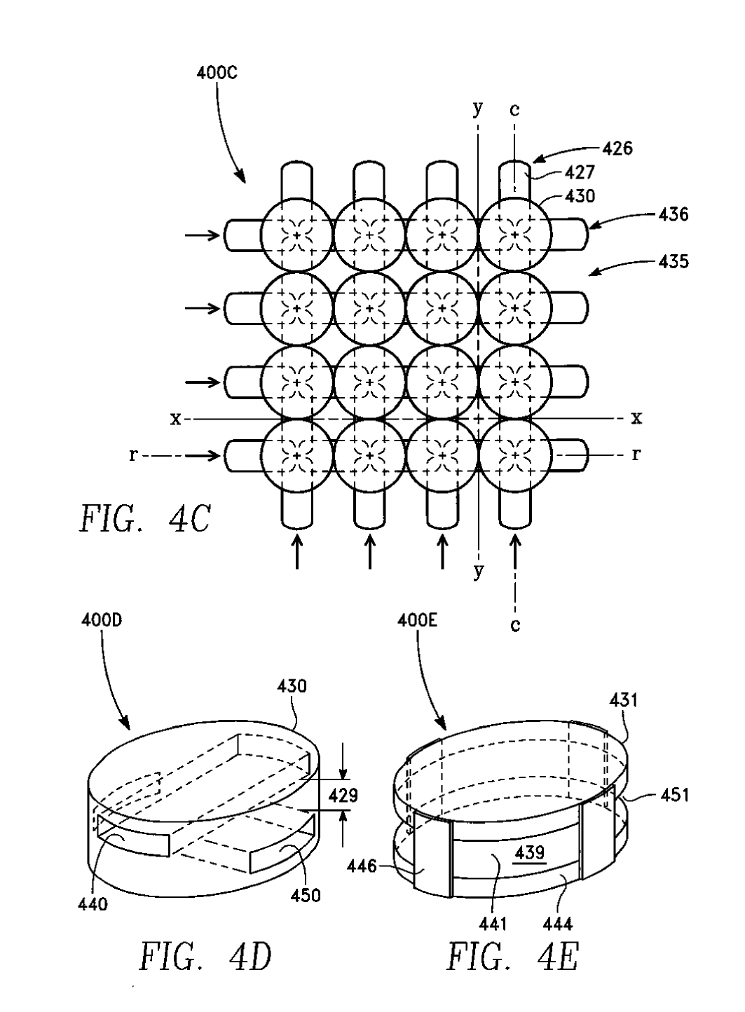

FIG. 4A shows a flopid structure with fold lines y-y and a translating engagement member 400A. The flopid structure 402, 408 includes a plurality of flopid elements 410 and a plurality of fold lines therebetween 412.

FIG. 4B shows an enlarged view of a flopid element 400B. A side passageway 420, for receiving an engagement member 404, 406, penetrates the flopid element 410.

The engagement member includes adjacent engagement segments 414 and is shown inserted in the flopid elements in two relative positions 402, 408. In addition, the engagement member is shown removed from the flopid elements to illustrate engagement member/segment positions relative to the flopid elements 404, 406.

Each engagement segment is about the same length as the passageway 420. When the engagement member is inserted through the flopid elements 410, it creates a floppy arrangement in one state and a rigid arrangement in another state.

A floppy arrangement 402 results when engagement segments 414 are substantially contained within respective passageways 420. In this position, the engagement segment does not interengage adjacent flopid elements 410.

A rigid arrangement 408 results when engagement segments 414 extend from the passageway in one flopid element 420 into the passageway of an adjacent flopid element. In this position, the engagement segment serves to interengage adjacent flopid elements.

In an embodiment, the engagement segments 414 are not interconnected. Here, a suitable means known to skilled artisans is used to maintain the engagement segments in the desired position. For example, an interference fit between the engagement segments and the passageways 420 or external means such as an engagement member actuator 418 provides means for maintaining engagement segment position and/or relative position of the engagement segments. Actuators include devices known to skilled artisans such as motors, solenoids, piezo-electric devices, and suitable prime movers.

In some embodiments, flexible web is used to interconnect adjacent flopid elements 410 in a manner similar to that described in connection with FIGS. 2C and 3C above. And, in some embodiments, the engagement segments 414 are interconnected via a flexible web 416 in a manner similar to that described in connection with FIGS. 2C and 3C above.

FIG. 4C shows a flopid structure having x-x and y-y fold lines and translating engagement members 400C. A plurality of flopid elements 430 are arranged in rows r-r and columns c-c forming an array of flopid elements 435.

FIG. 4D shows an enlarged view of a flopid element 400D. The flopid element 430 has a first side passageway 440 is for receiving an engagement member 426 lying along a column line c-c and a second side passageway 450 is for receiving an engagement member 436 lying along a row line r-r. As shown, the first and second passageways are spaced apart by a portion of the flopid element therebetween 429.

FIG. 4E shows an enlarged view of an alternate flopid element 400E. The alternate flopid element 431 has a first side passageway 441 for receiving an engagement member 426 lying along a column line c-c and a second side passageway 451 for receiving an engagement member lying along a row line r-r. As shown, the passageways are not spaced apart by a portion of the flopid element. Rather, flopid element spacers 446 create a common central cavity 439 through which the engagement members 426, 436 pass. In various embodiments, one or both of adjacent flopid elements 430, 431 and adjacent engagement segments 427 are interconnected by a flexible web as described in FIGS. 3C and 4A.

As described in connection with FIG. 4A above, engagement members 426, 436 having engagement segments 427 are movable with respect to adjacent flopid elements 430,431. Engagement member segments lying along a column line c-c are interengagable with adjacent flopid elements to resist flopid structure flexing along a column line c-c (as shown). Similarly, engagement member segments lying along a row line r-r are interengagable with adjacent flopid elements to resist flopid structure flexing along a row line r-r (as shown).

Engagement segment positions may therefore be chosen or switched to create flexible and rigid states along selected column and/or row lines. In some embodiments, engagement segment motions along a particular column or row line are opposed, providing both rigid and floppy characteristics simultaneously along a single row or column line. An exemplary implementation of this feature is where an engagement member has first and second sets of engagement segments, each set of segments being interconnected by a flexible web(s) 416. Independent movement of each set of segments by suitable actuating means, such as two actuators, provides the described functionality.

Use of retractable engagement devices provides another means of interengaging adjacent flopid elements. FIG. 4F shows an embodiment having retractable engagements 400F. A male flopid element 461 includes a body 468 and engagement segments 470, 472. In a retracted position 462, the engagement segments are substantially within one or more cavities in the flopid element body 473. In an extended position 464, the engagement segments project from opposed sides of the body.

A mating female flopid element 477 has a body 474 and a body cavity 476 (two shown) for receiving an extended engagement segment. In a mated configuration 466, a male flopid element 461 is adjacent to a female flopid element and an engagement segment 472 of the male flopid element extends into the cavity of the female flopid element.

As discussed above in connection with FIGS. 4A-C, duplicating the interengagement features on the male and female flopid elements provides an array of flopid elements and a flopid structure having x-x and y-y fold lines.

Use of rotating engagement arms provides another means of interengaging floppy elements. FIG. 4G shows an embodiment having rotating engagement arms 400G. A flopid structure 482, 483 is formed by a plurality of flopid elements 484, 486 having interposed fold lines y-y. As discussed in connection with FIG. 3C above, the flopid elements are in various embodiments interconnected by a flexible web. The flexible web may be strip-wise or continuous in alternate embodiments and is not shown here for clarity.

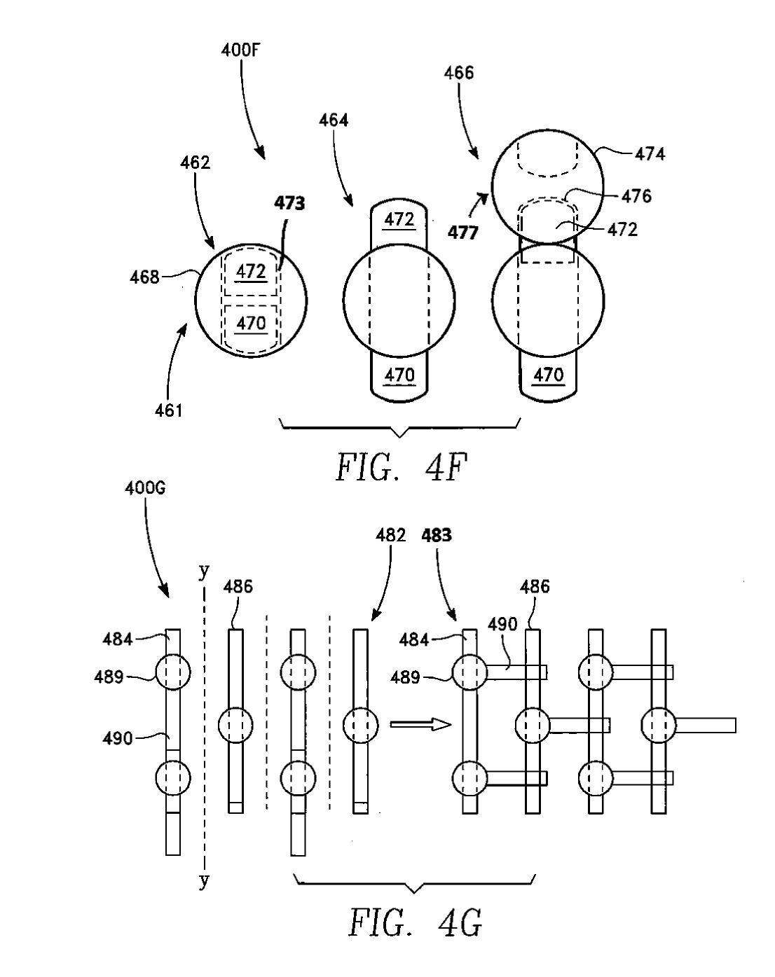

Each flopid element 484, 486 has rotatably coupled 489 engagement members 490. In a first state 482, the rotatable engagement members are positioned substantially parallel to the coupled flopid element so as not to interfere with flopid structure flexing about one or more fold lines y-y. In a second state 483, the rotatable engagement members 490 are rotated to engage an adjacent flopid element 486. The engagement can be any suitable means known to persons of ordinary skill in the art. For example, a slotted engagement feature similar to that of FIG. 5B may be used.

Use of a hub with radial engagement members provides another means of interengaging flopid elements. FIG. 5A shows radial engagement members arranged along x-x and y-y fold lines 500A. Flopid elements 509 are bounded by respective fold lines x-x and y-y. Each flopid element includes a radial engagement member including a hub 508 and four radial engagement segments 506 radiating from the hub. In a first state, the radial engagement segments of adjacent flopid elements are not engaged 502. In a second state, the radial engagement segments of adjacent flopid elements are engaged 520 via rotation of the radial engagement members.

In an embodiment, engagement 520 occurs when aligned radial engagement segments 510, 512 overlap 511. The engagement between the radial engagement segments may be by any suitable means known to persons of ordinary skill in the art. FIG. 5B shows an exemplary radial engagement 500B. Here, a radial engagement segment 512 is slotted to receive radial engagement segment 510. As will be appreciated by skilled artisans, the radial engagement members 504 in such case include alternating male 504 and female 505 types.

In some embodiments with radial engagements, it is desirable to maintain a particular spacing between the hubs of the radial engagement members 508. FIG. 5C shows hub spacing member(s) 500C. In particular, hub spacing member(s) 532 extend between hubs 508 to control the spacing therebetween. As will be obvious to persons of ordinary skill in the art, hub spacing can in another embodiment be accomplished by shafts, pivots, or similar means that interconnect respective hubs with a part or substrate of respective flopid elements.

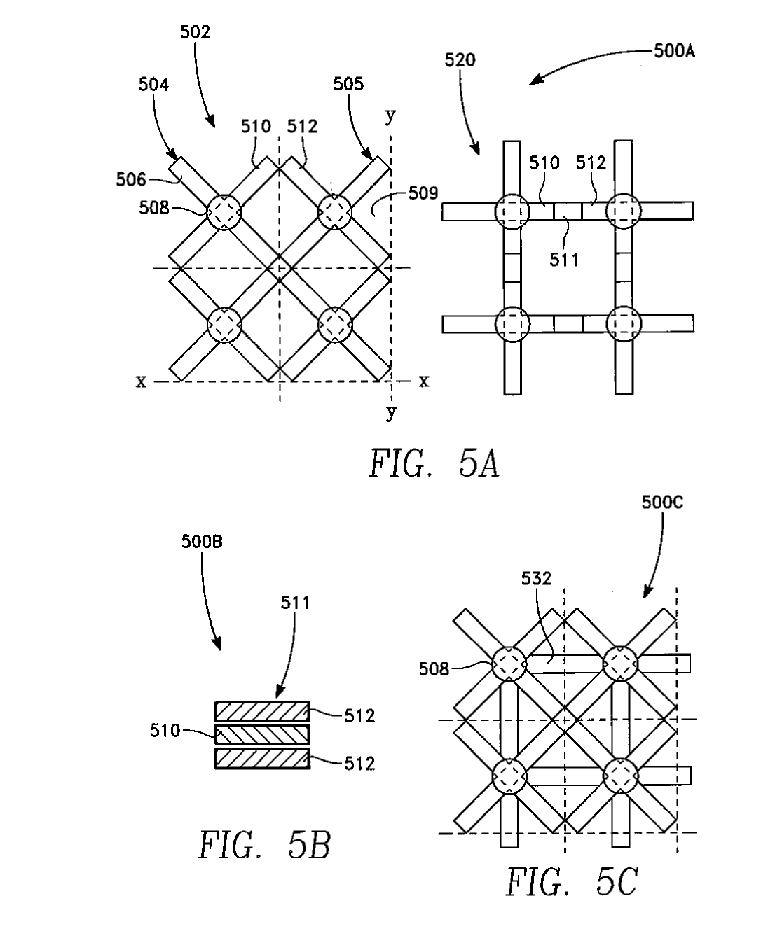

Use of gears provides a means for coordinated operation of radial engagement members. FIG. 6A shows gear operated radial engagement members 600A. FIG. 6B shows gears 602 located in a lower plane 610 are coupled, such as by a shaft 622, to radial engagement members 632 in an upper plane 630, 600B. FIG. 6C shows a perspective view of the meshed gears in the lower plane 640 for positioning male radial engagement segments 644 within slots of adjacent female radial engagement segments 642, 600C.

As a skilled artisan will understand, rotation of a single meshed gear 602 will cause rotation of all other gears that are directly or indirectly meshed 603 with the rotated gear. The interconnection between each rotating gear and its respective radial engagement member 632 causes simultaneous operation of the radial engagement members. A selected rotation of the single meshed gear can be used to simultaneously engage (as shown in FIGS. 6A and 6C) or disengage the male and female radial engagement segments 642, 644.

When the radial engagement segments 610, 612 are in a disengaged state, the floppy elements bounded by the fold lines x-x and y-y are free to flex about these fold lines. When the radial engagement segments are engaged, flexing of the floppy elements about the fold lines is restrained by radial segment interengagement 611. In various embodiments, hub spacing members and/or flopid element substrates similar to those discussed in connection with FIGS. 5C and 5A above are used to control hub spacing. As discussed in connection with FIG. 3C above, the flopid elements are in various embodiments interconnected by a flexible web. The flexible web may be strip-wise or continuous in alternate embodiments and is not shown here for clarity.

During operation, the flopid structures discussed above are alternately floppy and rigid, the state being switchable in response to motion of one or more engagement members. There are various applications for such flopid structures. In some applications, use of a flexible sheet form body is enhanced by interconnection with a flopid structure such as that of one or more of FIGS. 2A-C, 3A-C, 4A, 4C, 4F, 4G, 5A, 5C, 6A.

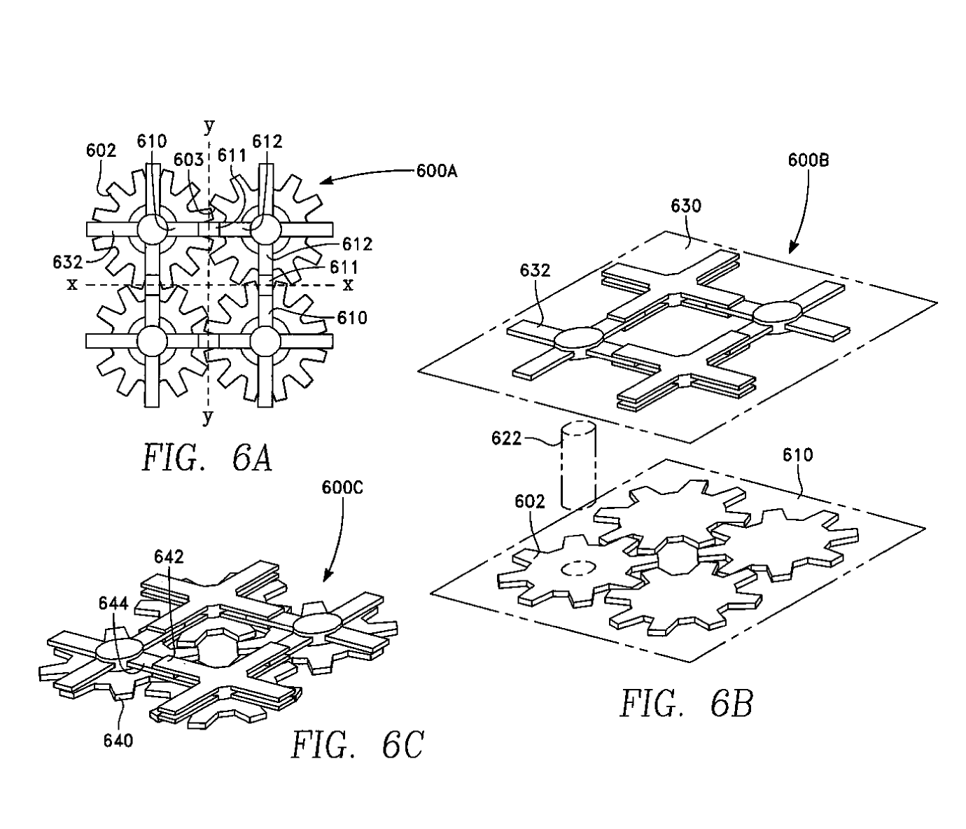

FIG. 7 shows a flopid structure interconnected with a flexible sheet form body 700. A plurality of flopid elements 702 of a flopid structure 703 are interconnected by members such as support members 714 to a sheet form body 713. For clarity, the sheet form body and the flopid structure are shown spaced apart with exemplary support members. In various embodiments, the support members are for supporting and/or interconnecting a flopid structure and a sheet form body. In some embodiments, the flexible sheet form body is a light emitting electronic display device such as an LED display or similar electronic display.

Operation of engagement members as explained above switches the flopid structure 703 between floppy and rigid states. Switching the flopid structure to a floppy state enables the sheet form body 713 to flex with the flopid structure. In this manner, flexibility is imparted to the sheet form body. Switching the flopid structure to a rigid state restrains the flexibility of the sheet form body. In this manner, rigidity is imparted to the sheet form body.

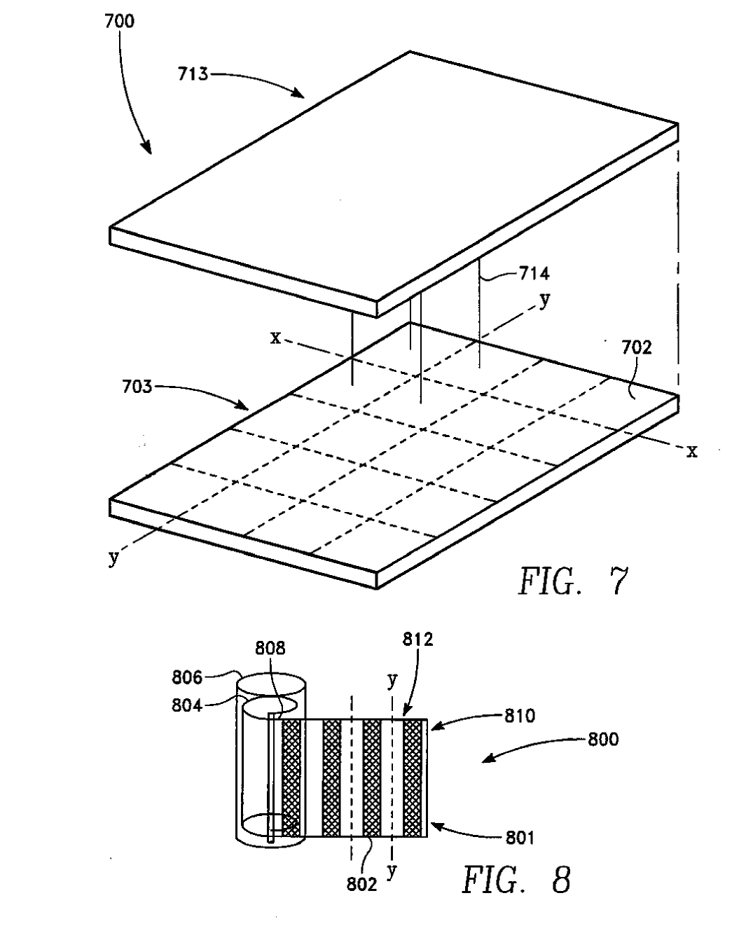

In some applications, use of a scrollable body is enhanced by interconnection with a flopid structure such as that of one or more of FIGS. 2A-C, 3A-C, 4A, 4C, 4F, 400G, 5A, 500C, 600A. FIG. 8 shows a scroll application of a flopid structure 800. A scrollable body 801 has flopid elements 802. While in a flexible state, the scrollable body can be rolled into a scroll 804, for example during scrolling into a scroll can 806 through a scroll can slot 808. The scrollable body can also be unscrolled while in a flexible state, for example when it is drawn out of the scroll can. Switching all or portions of the scroll to a rigid state enhance the utility of the screen as in, for example, touch screen applications.

In an embodiment, the scrollable body 801 includes a display screen front portion 810, such as a flexible LED display screen, and a flopid structure rear portion 812.

In some embodiments fold lines y-y are implemented using an engagement arm structure similar to that of FIG. 4G. And, in some embodiments removal or return of the scroll 801 to the scroll can 806 actuates the engagement arms at each fold line as it passes through the scroll can slit 808. For example, fingers or brushes such as fingers or brushes of the scroll can slit can be used to brush the engagement arms into a rigidizing position during screen extraction and into a flexible position during screen roll-up. In various embodiments brushes include a plurality of adjacent, elongated and resilient fibers and/or rods.

In another embodiment fold lines y-y are implemented using geared radial engagement members similar to those of FIG. 6A. And, in some embodiments removal or return of the scroll 801 to the scroll can 806 actuates the radial engagement members as each fold line as it passes through the scroll can slit 808. For example a single fixed gear, such as a gear of the scroll can or scroll can slit, meshing with a single traveling gear on the scroll is used to switch the scroll 801 to a rigidized state during screen extraction and into a flexible position during screen roll-up.

The present invention has been disclosed in the form of exemplary embodiments; however, it should not be limited to these embodiments. Rather, the present invention should be limited only by the claims which follow where the terms of the claims are given the meaning a person of ordinary skill in the art would find them to have.

What is claimed is:

1. A flopid structure for enhancing the utility of a flexible device comprising:
a flexible device coupled to an array of flopid elements;
the array of flopid elements including plural flopid elements interconnected by one or more flexible members establishing one or more fold lines;
a plurality of rigid engagement members;
each engagement member operable to resist forces tending to flex a flexible member when the engagement member is in a first state;
each engagement member operable to present substantially no resistance to forces tending to flex a flexible member when the engagement member is in a second state;
the flopid array operable to impart rigidity to the flexible device when the engagement members are in the first state; and,
the flopid array operable to impart flexibility to the flexible device when the engagement members are in the second state.

2. The flopid structure of claim 1 wherein the flexible members are flexible webs.

3. The flopid structure of claim 2 wherein a plurality of engagement elements are retractable into a single flopid element.

4. The flopid structure of claim 2 wherein the operation of the engagement members includes rotation of a plurality of the engagement members.

5. The flopid structure of claim 2 wherein operation of the engagement members includes translation of a plurality of the engagement members.

6. The flopid structure of claim 5 further including along a particular fold line a first actuator operable to selectively interengage a first set of flopid elements and a second actuator operable independent of the first actuator to selectively interengage a second set of flopid elements to simultaneously provide both floppy and rigid states along the fold line.

7. The flopid structure of claim 6 further including a first plurality of fold lines substantially perpendicular to a second plurality of fold lines.

8. The flopid structure of claim 7 wherein the flexible device is a light emitting electronic display screen coupled to the flopid array via a plurality of elastic supports therebetween.

9. The flopid structure of claim 4 further including:
a scroll can for containing the flopid array,
a brush coupled to the scroll can operable to switch engagement members to an interengaging state on withdrawal of the flopid array from the scroll can; and,
the brush operable to switch engagement members to a disengaged state on return of the flopid array to the scroll can.

10. A flopid structure for enhancing the utility of a flexible device comprising:
a flexible device coupled to an array of flopid elements;
the array of flopid elements including plural flopid elements;
a plurality of engagement members;
each engagement member including a plurality of engagement segments, each engagement segment coupled to another engagement segment by a flexible member;
each engagement member engaged with a plurality of the plural flopid elements;
each engagement member operable to resist forces tending to flex the engaged plurality of flopid elements in a first state;
each engagement member operable to present substantially no resistance to forces tending to flex the engaged plurality of flopid elements in a second state;
the flopid array operable to impart rigidity to the flexible device when the engagement members are in the first state; and,
the flopid array operable to impart flexibility to the flexible device when the engagement members are in the second state.

11. The flopid structure of claim 10 wherein the flexible members are flexible webs.

12. The flopid structure of claim 11 wherein a plurality of engagement elements are retractable into a single flopid element.

13. The flopid structure of claim 11 wherein the operation of the engagement members includes rotation of a plurality of the engagement members.

14. The flopid structure of claim 11 wherein operation of the engagement members includes translation of a plurality of the engagement members.

15. The flopid structure of claim 14 further including along a particular fold line a first actuator operable to selectively interengage a first set of flopid elements and a second actuator operable independent of the first actuator to selectively interengage a second set of flopid elements to simultaneously provide both floppy and rigid states along the fold line.

16. The flopid structure of claim 15 further including a first plurality of fold lines substantially perpendicular to a second plurality of fold lines.

17. The flopid structure of claim 16 wherein the flexible device is a light emitting electronic display screen coupled to the flopid array via a plurality of elastic supports therebetween.

18. A flopid structure for enhancing the utility of a flexible device comprising:
a flexible device coupled to an array of flopid elements;
the array of flopid elements including plural flopid elements;
each of the plural flopid elements including a gear located in a lower gear plane and an engagement member located in an upper engagement member plane;
each of the gears interengaging at least one other gear;
one gear operable to cause rotation of a plurality of gears and interengagement of a plurality of engagement members for resisting forces tending to flex at least a portion of the array along a fold line in a first state;
the gear operable to cause rotation of a plurality of gears and disengagement of a plurality of engagement members for presenting substantially no resistance to forces tending to flex at least a portion of the flopid array along the fold line in a second state;
the flopid array operable to impart rigidity to the flexible device when the engagement members are in the first state; and,
the flopid array operable to impart flexibility to the flexible device when the engagement members are in the second state.

19. The flopid structure of claim 18 further including one or more flexible webs interconnect a plurality of flopid elements in the flopid array.

20. The flopid structure of claim 18 further including a first plurality of fold lines substantially perpendicular to a second plurality of fold lines.

21. The flopid structure of claim 18 further including:
a scroll can for containing the flexible device and array of flopid elements;
a stationary gear coupled to the scroll can operable to switch engagement members to an interengaging state on withdrawal of the flopid array from the scroll can;
the stationary gear operable to switch engagement members to a disengaged state on return of the flopid array to the scroll can; and,
wherein the flexible device is an electronic light emitting display coupled to the flopid array via a plurality of elastic supports therebetween.
